(19) United States
(12) Patent Application Publication
(10) Pub. No.: US 2006/0198208 A1
(43) Pub. Date: Sep. 7, 2006

(54) Publicasting systems and methods

(75) Inventors: Nicholas J. Witchey, Laguna Hills, CA (US); Curtis D. Brown, Dove Canyon, CA (US)

Correspondence Address: ROBERT D. FISH;RUTAN & TUCKER LLP, 611 ANTON BLVD 14TH FLOOR, COSTA MESA, CA, 92626-1931, US

(73) Assignee: Lantronix, Inc.

(21) Appl. No.: 11/075,266

(22) Filed: Mar. 7, 2005

(51) Int. Cl. G11C 7/10

(52) U.S. Cl. 365/189.05

(57) ABSTRACT

An add-on module provides publicasting functionality to legacy and other devices. Contemplated modules include: (a) a transformation agent that transforms device data to a desired publishable data format for insertion into a remote application, and (b) a consumer interface that publicasts the device data as publishable data to a remote device data consumer. Implementations are contemplated for both legacy devices that lack complete publicasting capability, and newly developed devices for which the developer desires a ready-made implementation of publicasting functionality.

### FIELD OF THE INVENTION

The field of the invention is data acquisition from HVAC devices.

### BACKGROUND

Over the last decade or two the number of devices used to interact with an environment and collect data has grown exponentially. As the costs of such devices decrease, the number of devices will grow even larger as the devices work their way into nearly ever nook and cranny of our every day lives. Devices will be so ubiquitous that people will no longer notice their presence. HVAC systems offer a prime example of such systems.

Many problems have arisen due to the sheer numbers of devices in an HVAC environment and the sheer amount of data the devices produce for a single building, let alone a campus where multiple buildings must be maintained. For instance, as buildings age the software applications that utilize device data change from one application to another as the years pass. In addition, as time passes, multiple applications wish to consume the device data simultaneously. Consequently, the data format used by the devices to transport data to the applications may no longer be relevant to new and different applications. Therefore, expensive intermediaries must be developed to access device data and transform it to its final desired format. Or, even worse, the building must be re-instrumented with new devices that better fit with the over all software system at huge costs. Even if this could be done cost effectively, the problem still remains that applications desiring use of the device data will evolve over time. Therefore, there is a need for a mechanism that allows for device data to be adapted to fit the changing environment.

Another problem centers on how the devices coordinate their activities. Nearly all HVAC devices are end-points that communicate directly through serial lines or network connections to a central hub or gateway that collects the information or passes it on to a remote central software system that consumes the device data. As HVAC systems evolve over time, devices will grow interdependently and will need to communicate directly with each other to increase energy efficiency without having to relay data through the central data consumer, which can cause delays in processing. For instance, if the temperature in a room exceeds a threshold value, it makes most sense for the thermostat to directly instruct an AC unit to cool the room. When dealing with large buildings and extensive campuses allowing for fine grained control over HVAC systems at the device level can offer extensive savings to the building or campus owners. Therefore, there remains a need for devices to consume each other's data and take actions in a coordinated manner. Devices are quickly becoming consumers of other devices' data.

Furthermore all standards used to communicate device data to a remote application or other device data consumers shift as new technologies evolve. Originally, devices used direct serial connections to communicate information directly to a single application. Then serial protocols evolved to frame data so remote applications could collect the data more easily in a portable manner. Many companies such as Echelon™ use proprietary protocols such as LonWorks™ for device communication to ensure stability in the building environment. Unfortunately, Echelon's approach, while advantageous to Echelon, locks customers into specific implementations that are not robust against evolving standards. For instance, the American Society of Heating, Refrigerating and Air-Conditioning Engineering, Inc (ASHRAE) is guiding the new BACNet standard to use XML and web services to provide access to device data. Once the standard is complete, devices can be built to integrate into larger distributed applications spaces. Even still, devices using the new standard will have only the capabilities programmed into them at manufacturing time and even worse, legacy devices will not be able to participate in the new paradigm because they can not be upgraded cost effectively. Nor can pre-programmed devices have their capabilities updated simply based on the type of application that wishes to access the device data. Consequently, there is still a need for adapting device data to a format that fits the needs of a remote consumer or application.

Beyond the changing standards, the methods and applications that people use to naturally interface with devices has also been changing. Efforts to provide access to device data have been centered on the opaque needs of a software application. Device data is largely un-accessible to the people who actually need to consume the data for analysis. People wish to view data in a natural manner including a graph, news item, alert, email, or other human-centric manner in real-time. Large expensive applications are required to manipulate the data from the device format to a final format the user wishes to use. Consequently, people require a more natural, cost effective method for accessing device data in formats that fit their applications. This is especially true because building installations are rapidly moving from device centric applications to data centric applications. For instance, people who consume device data wish to have spreadsheets or databases directly populated from a device. In the future, even more natural methods of communication will be desirable such as instant messaging which can be used to send alerts from devices directly to individuals anywhere in the world. The need for more natural methods of publishing device data to a remote consumer continues to grow.

Some companies have attempted to address the issues of accessing legacy device data. Companies such as Lantronix™ produce device servers that interface to legacy devices via a serial interface and tunnel device data over TCP/IP. Device servers provide excellent device connectivity; however, they passively pass device data unaltered to a remote device data consumer. A need still remains for a module capable of packaging device data into a format that fits the needs of the target consumer. For instance, if the consumer is a spreadsheet application and the user wishes a graph of temperature as a function of time the user could access an HVAC thermostat anywhere on a campus via the spreadsheet application. A module connected to the thermostat can convert the temperature data to a comma separated value (CSV) data set and publish it directly to the application where the data directly populates the cells of the worksheet.

Companies such as emWare™ have attempted to address the need for connecting devices to remote consumers by providing modules that convert device data to a format that can be easily stored in a remote database. Unfortunately, emWare's approach uses a proprietary protocol and an implementation specific conversion method. In addition, the data must be stored in emWare's remote database, from which the consumer must pull the data. There still remains a need for a consumer to determine which publishable data format it requires and a need for the module to have a set of transformation rules that match the needs of the consumer.

Finally, the ever growing number of devices, such as those deployed in HVAC systems, coupled with evolving standards, and the natural communication methods and formats of data consumers, have resulted in several problem that must be addressed:
Data consumers need a method to access device data using desired publishable data formats
Legacy devices and new devices need the ability to adapt to a changing communication environment
Legacy devices and new devices require the ability to transform data into a desired publishable data format
Legacy devices and new devices require the ability to respond to remote data consumers in a manner that the consumer will find natural by producing a data feed

Thus, there remains a considerable need for methods and apparatus that allow remote consumers to access device data based on desired formats and receive data feeds. Remote consumers could be software applications, other devices, databases, presentations, spreadsheets, or other entities that require a need for data. The term “publicasting” is used herein to describe the mechanism to fulfill these needs. Publicasting embodies the ideas of publishing data in a desired format and broadcasting the data to a number of remote consumers possibly through a data feed.

### SUMMARY OF THE INVENTION

The present invention employs a module to provide publicasting functionality to legacy and other devices that enable the device to publish device data to remote device data consumers. Contemplated modules include: (a) a transformation agent that transforms device data to a desired publishable data format, and (b) a consumer interface that publicasts the data in the desired format to a remote device data consumer. The apparatus and methods disclosed herein are of great interest to companies and individuals with a large number of deployed legacy devices collecting data and who wish to integrate the data into different and newly deployed software applications. Implementations are also contemplated for newly developed devices where a developer desires a ready-made solution for publicasting device data.

From another perspective, it can be said that embodiments of the inventive subject matter publicast device data through a consumer interface using methods that involve: (a) providing a module that communicates bi-directionally with the device at least in part through a device interface, and (b) transforms the data into a publishable data format as desired by a remote device data consumer.

From yet another perspective, embodiments of the inventive subject matter insert device data in the form of publishable data into a remote application by employing a system that includes: (a) a device with limited publicasting capability, (b) a remote application that requires data from the device, and (c) a publicasting module that transforms the device data into a desirable publishable data format for the application.

One possible embodiment of a publicasting module may include using serial interfaces including RS-232, RS-485, or RS-422 for the device interface to the device. The module's transformation agent transforms the device data collected over the serial interface to SQL commands that can be publicasted to remote databases via an Ethernet consumer interface. Yet another possible embodiment of a publicasting module could transform the device data to web services, possibly employing WSDL, which can be used to communicate directly with a remote application that consumes data from the device. The inventive subject matter in further embodiments contemplates all forms of information communications between the device and publicasting module, and all same or differing communication techniques between the module and remote device data consumer.

The teachings herein may be advantageously employed by companies and developers to access device data via a publicasting module and insert the device data into remote applications. Publicasting modules may be employed to access device data from various classes of devices including stand-alone devices or collections of devices. Stand-alone devices include printers, office equipment, projectors, sensors, console servers, device servers, management modules, or access control systems and collections of devices include server farms or sensor arrays as in an HVAC system. In addition the modules are self contained units that integrate directly into larger product units or external boxes that plug into legacy devices or rack mount systems that provide management to other rack systems including servers.

Various objects, features, aspects, and advantages of the present invention will become more apparent from the following detailed description of the preferred embodiments of the invention, along with the accompanying drawings in which like numerals represent like components.

### BRIEF DESCRIPTION OF THE DRAWING

FIG. 1 is a schematic of a module according to the inventive subject matter, providing publicasting capability to a device through a device interface, sending publishable data to a remote consumer.

FIG. 2 is a graphical representation depicting the logical blocks and data flow for a publicasting module.

FIG. 3 is a representation of a possible physical construction of a publicasting module.

FIG. 4 is a representation of a method used by a remote device data consumer to request data feeds from the publicasting module.

### DETAILED DESCRIPTION

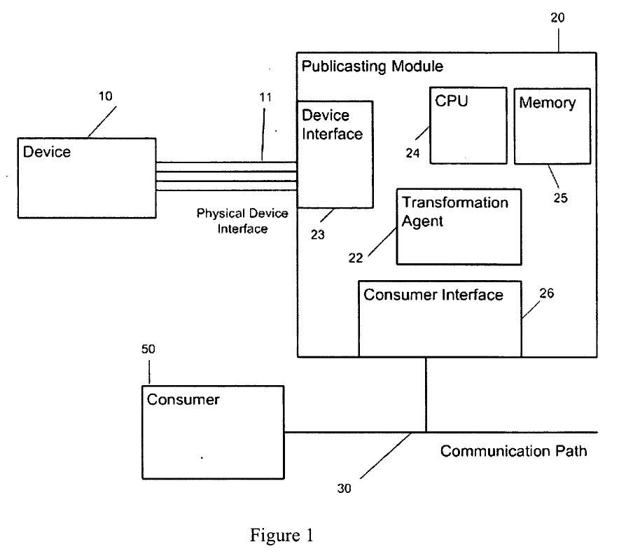

In the very simple embodiment of FIG. 1, a device 10 has a physical interface 11 that communicates with a publicasting module 20. The module and device communicate bi-directionally over interface 11. The module includes a device interface 23 comprising a combination of hardware, software, or firmware with the responsibility of interacting with device 10. Module 20 also includes a transformation agent that is responsible for transforming device data gained from device 10 to publishable data. In addition, module 20 includes a consumer interface 26 that connects to a remote device data consumer 50 over a communication path 30.

Module 20 can be implemented in any combination of software, hardware, or firmware. Typically, module 20 contains a CPU 24 and a memory 25 for running software or firmware and physical interfaces for interacting with a device and remote consumers. Even though FIG. 1 implies a module composed of hardware coupled with firmware, it is also contemplated that the module may comprise only software elements where interfaces 23 and 26 are actually APIs and communication path 30 includes internal buses or memory transfers. In such an embodiment, the software would run on a computer system using a general purpose operating system such as Linux or Windows. In this case, the device could be another application running on the same system or a physical device connected to the host computer.

Although FIG. 1 depicts a single set of interfaces, it is also contemplated that module 20 may support multiple such interfaces to provide publicasting capabilities for multiple devices to multiple consumers.

Device Interface

The first physical device interface 11 (or set of interfaces) on module 20 is designed for interacting with a target device. These interfaces can advantageously be implemented as serial interfaces (such as physical device interface 11), and comprise a set of at least one data wire and/or additional wires for data or transmission and reception control (flow control). This interface may also be wireless using any information communications technology or protocol implemented between device 10 and module 20.

All currently known serial interfaces are contemplated, as well as those that are developed in the future. Currently contemplated standards for such interfaces include, for example, I2C, SPI, CAN, Profibus, RS 232, RS 485, RS 422, USB, Ethernet, or even Gigabit Ethernet. Further contemplated interfaces include existing Low Pin Count (LPC) interfaces or future LPCs whether serial in nature or not. Certainly, where a given module has multiple serial interfaces, those interfaces can be of different types (i.e., operate using different standards). Depending on the application, a contemplated serial interface could be built based on a set of general purpose programmable I/O (GPIO) pins. Such pins can be driven by software running on the module's CPU or the device's CPU implying the GPIO pins also provide a serial I/O interface. It is also contemplated that GPIO pins may be used for non-serial based communication including determining power status of the device, triggering specific events, or controlling the device.

Connection from physical device interface 11 to the module 20 can be accomplished in any desired manner, including hardwiring through phone lines, cables, connectors, soldering, over the Internet, or LAN in any form existing or in the future, wired or wireless.

Beyond serial and LPC interfaces, it is also contemplated that physical device interface 11 may be a parallel interface allowing for larger amounts of data to flow between device 10 and module 20. Contemplated parallel interfaces include PCI, CompactPCI, standard 25-pin connector, or others.

Because device interface 23 may include Ethernet and networking capabilities, it is specifically contemplated the device interface may connect to a consumer interface of another module so the modules may work together. In such a configuration, a publicasting module would publicast device data to another module that could collect and possibly further concentrate and transform the data to a final application. It is also specifically contemplated device interface 23 may employ APIs to communicate with device 10.

Consumer Interface

The second interface (or set of interfaces), consumer interface 26 is designed for interacting with remote device data consumers. These interfaces generally provide network access or remote access to consumer 50. Typical consumer interfaces 26 are Ethernet, 802.11a/b/g, ATM, or others. These interfaces are used to send data and data feeds over a communication path 30. Examples of communication path 30 may employ packet switched networks including LANs, WANs, WLANs, or Internet.

Additional interfaces (not shown) may also be present within or on module 20 to provide user interfaces, control over module 20, power, or even a method to place security parameters within module 20 via a trusted path.

Additional contemplated consumer interfaces include APIs for cases where the consumer and module wish to communicate using high level programming languages.

In some embodiments, the consumer interface may directly connect to the device interface of another publicasting module to enable multiple modules to work together in a meaningful fashion.

Transformation Agent

Module 20 includes a transformation agent 22 whose main responsibility is to transform device data from device 10 to publishable data. Agent 22 includes several other responsibilities including interacting with device interface 23 to collect device data, transforming device data to a publishable data format, and interacting with consumer interface 26 by responding to requests for publishable data.

Agent 22 provides device data transformation through a number of contemplated transforms including: a complete filter, pass through, data subtraction, data addition, translation, conversion, transposition, application of a function, take action, canonical formatting, data creation, or combination of the previous items. All possible device data transformations are contemplated.

It is contemplated that the transformations applied to the device data are governed by a set of rules. The rules used by the transformation agent may be defined through a number of differing mechanisms including being defined by the developer of the module at manufacturing time, determined by the type of request made by remote consumer, updated by users of the module using scripting languages, determined by the type of device the module is connected to, or other contemplated mechanisms. It is further contemplated that the rules for transformation are applied to the device data to create publishable data for publication via a data feed. Therefore, the transforms mentioned previously can be described in greater detail by how the resulting data feed content differs from the original device data as indicated by the following items:
Complete Filter: Data feed comprises no device data
Pass Through: Data feed comprises un-altered device data
Data Subtraction: Data feed has some device data removed
Data Addition: Data feed has extra information included in device data including time stamps, state information, or other data elements
Translation: Data feed comprises individual device data elements placed into a new desired format
Conversion: Data feed comprises new data elements created based on device data elements
Transposition: Data feed comprises device data elements re-ordered based on desired rules
Application of Function: Data feed comprises results from the agent applying a function to the device data including creation of a graph or other results
Take Action: Data feed comprises results from agent taking an action based on the device data including power toggled, reset system, or other actions.
Canonical Formatting: Data feed comprises placing device data into a desired standardized format including LonWorks, BACNet, ModBus, or others.
Creation: Data feed comprises new data including status information not relating to device data
Combination: Any combination of the above.

It is also contemplated that agent 22 has additional responsibilities including providing state for device 10, executing functions within the module, controlling possible module interfaces including power and resets, maintaining internal data stores, passing commands through the module directly to the device, or other responsibilities necessary to support publicasting capability for device 10.

Agent 22 interacts with device interface 23 to query or to interrogate device 10 to gain device data. Such queries and interrogations may include device configuration, power cycling, or other device centric activities.

Agent 22 also is communicatively coupled with consumer interface 26 to coordinate proper responses to requests from consumer 50. Such responses may include proper formatting of data feeds, updating transformation rules, or even configuration of module 20.

Multiple Devices

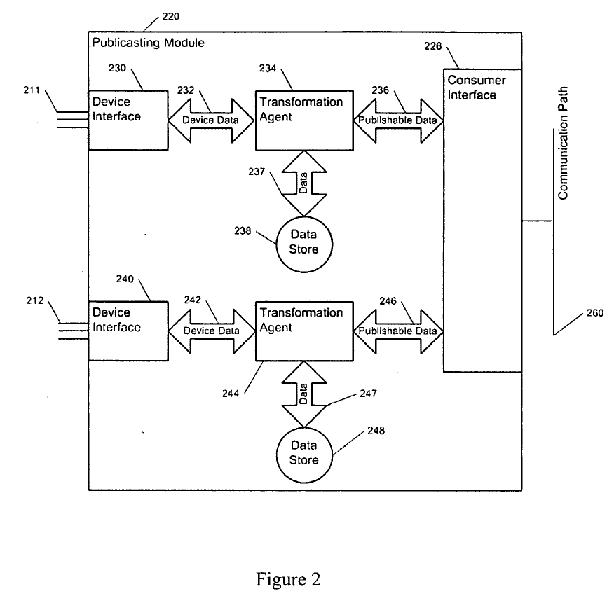

FIG. 2 depicts a possible embodiment of publicasting module 220 capable of providing publicasting capabilities for multiple disparate devices. In addition, logical data paths are shown. Physical device interfaces 211 and 212 provide access to devices (not shown) requiring publicasting capabilities. Device interfaces 230 and 240 embody the necessary hardware, software, or firmware to understand the target devices. As interfaces 230 and 240 collect device data 232 and 242 respectively, the device data is sent to transformation agents 234 and 244. As device data is collected, both transformation agents store data 237 and 247 into data stores 238 and 248 which can be used to provide state for the target devices. In addition, transformation agents also apply previously defined transformation rules to device data 232 and 242 directly or data stored in the data store. When the transformation agents receive requests through consumer interface 226, the agents provide consumer interface 226 with publishable data 236 and 246. Consumer interface 226 then publishes the data as a data feed to remote consumers.

Although module 220 depicts capability of handling two devices, it is specifically contemplated that a module is capable of handling any number of devices from one to many. More specifically, it is contemplated that a publicasting module is capable of supporting two devices. Additional devices may be supported by simply replicating the logical functionality described for each device.

The description of module 220 publicasting for multiple devices is not meant to be restrictive, but rather to present a possible path for implementation. Many other possible implementations are possible to serve the need for publicasting from multiple devices including single monolithic executables, a single transformation agent handling all devices, a single shared data store, coordinated communications amongst possible logical blocks, or any other possible technique employed by those skilled in the art.

Publicasting Module Data Flow

Data flows bi-directionally through module 220. Referring to the top portion of FIG. 2, device interface 230 has responsibility for communicating over physical device interface 211 using low-level raw data communication mechanisms. Device interface 230 comprises sufficient complexity, including hardware or firmware, to understand the low-level raw data as well as device level communications in order to package the device data 232 for communication with transformation agent 234. It is contemplated that device interface 230 may comprise necessary information to manage the target device including configuration, control, data acquisition, monitoring, GPIO status, or even power management. In addition, it is possible device interface 230 may communicate with the target device without communicating with transformation agent 234. Device interface 230 also has responsibility for accepting device data 232 from transformation agent 234. Under such conditions, interface 230 converts device data 232 into device specific raw data sent over physical interface 211 including wired or wireless interfaces.

Device data 232 flows bi-directionally between device interface 230 and transformation agent 234. A number of contemplated methods of transferring the device data can be used including direct memory copies, use of APIs, shared memory, or other standard software engineering techniques for sharing data between two logical blocks of code, in the embodiment wherein 230 and 234 are implemented as code. Other embodiments for the logical blocks, including ASICs or LSI blocks, are also contemplated. Transformation agent 234 also stores and retrieves data 237 from data store 238. Interactions with data store 238 may also include standard software engineering techniques including using file system APIs, memory copies, or other mechanisms. When necessary as determined by the transformation rules, transformation agent 234 generates publishable data 236 based on device data 232 and data 237. Again, standard software techniques may be employed to communicate publishable data 236 bi-directionally with consumer interface 226.

Finally, consumer interface 226 is responsible for interacting bi-directionally with transformation agent 234 and to any entities external to the target device or module 220 including remote consumers, networking applications, software packages, internet hosts, or other entities that require access to the target device or module 220. It is contemplated that consumer interface 226 may include all necessary hardware, software or firmware to communicate at a low-level over communication path 260. In the preferred embodiment, communication path 260 comprises a packet switched network. Consumer interface 226 also comprises sufficient complexity to understand various protocols used to communication with other hosts. Communication protocols include TCP/IP, UDP/IP, XML, WSDL, web services, HTTP, FTP, or other network or Internet related protocols. Additional future communications protocols are also contemplated as they are developed and gain currency.

In all cases, communications between logical blocks may be best implemented using standard software techniques; however, all possible techniques that result in meaningful access to data are contemplated.

Publicasting Module Platform

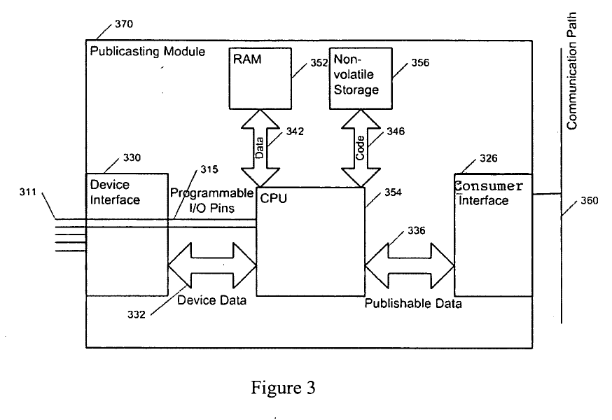

FIG. 3 displays a block diagram representing a preferred platform of the publicasting module. The publicasting module has housing 370 encasing device interface 330, CPU 354, RAM 352, non-volatile storage 356, and consumer interface 326. In addition housing 370 also encloses necessary buses and communication lines between the various components. Housing 370 is optional and the module may be provided without a separate container or housing and could be integrated into the target device, or any other combination of physical partitioning with other system components. Even though FIG. 3 shows an embodiment, other possible configurations are contemplated. For instance, the RAM and non-volatile storage could be combined with CPU 354 into a single chip solution. The publicasting platform includes all the software, firmware, hardware, interfaces, or necessary components to enable the publicasting module to function with devices and remote consumers. Other contemplated platforms for the publicasting module include sufficient components to enable handling multiple devices requiring multiple physical interfaces.

Device interface 330 provides connectivity to the device and passes device data 332 to CPU 354. In addition, device interface 330 provides access to programmable I/O pins 315 from the device to CPU 354. CPU 354 runs the necessary software or firmware to control the publicasting module and stores data in RAM 352. The code that executes on CPU 354 is stored in non-volatile storage 356 which can include flash, EEPROM, or even a hard drive. Consumer interface 326 connects CPU 354 to the communication path 360 and provides a path for external data including TCP/IP data.

A number of configurations are contemplated for publicasting module 370 which can range from small embedded processors containing the complete logical functionality shown in FIG. 3 to full size rack mount computer systems. The publicasting module also includes firmware infrastructure to support the modules application. Firmware includes TCP/IP stack, operating system, file system, web servers, FTP servers, or other networking protocols. Beyond publicasting, the publicasting module also supports configuration for itself as well as configuration for the device.

The physical nature of the platform supports the running of software or firmware for the module to supply the logical functionality depicted in FIG. 2. A preferred embodiment will separate each of the logical blocks into functional units that communicate together. Other embodiments include combining all functional elements into a single monolithic executable image, or separating the logical elements into smaller parts. Yet other embodiments may include all necessary rules and firmware drivers placed into the module at manufacturing time for a specific set of devices and consumers.

Implementations

A preferred embodiment of the publicasting module 370 is a small compact device that can be integrated easily into a device's product design, similar in its size and modularity to the Lantronix™ XPort™. Such an implementation would allow for both publicasting device data from legacy devices, and inclusion into newly developed devices. It is specifically contemplated that publicasting module 370 fit within a standard physical connector including an RJ-45 jack or a serial connector.

The publicasting module 370 can be embodied in a number of physical forms depending on the target application. A single chip or ASIC could be constructed to house the necessary CPU, memory, and physical interfaces to accomplish the publicasting capabilities. A software developer's kit would provide all the necessary software components to support the chip. Another embodiment could be a small single board computer that can be integrated into a larger product similar to the Lantronix Micro product. Yet another embodiment could be an external box level product that could attach serially or otherwise to the device similar to the Lantronix line of device servers. Depending on the configuration of the publicasting module, it could supply and/or receive power from its physical interfaces using power over Ethernet.

Specific implementations of publicasting module 370 are contemplated including publicasting modules that employ RS-232 serial interfaces for device interfaces and publishing data feeds using SQL commands or publishing data feeds using web services where the remote consumers are databases or software applications, respectively.

Publicasting Methods

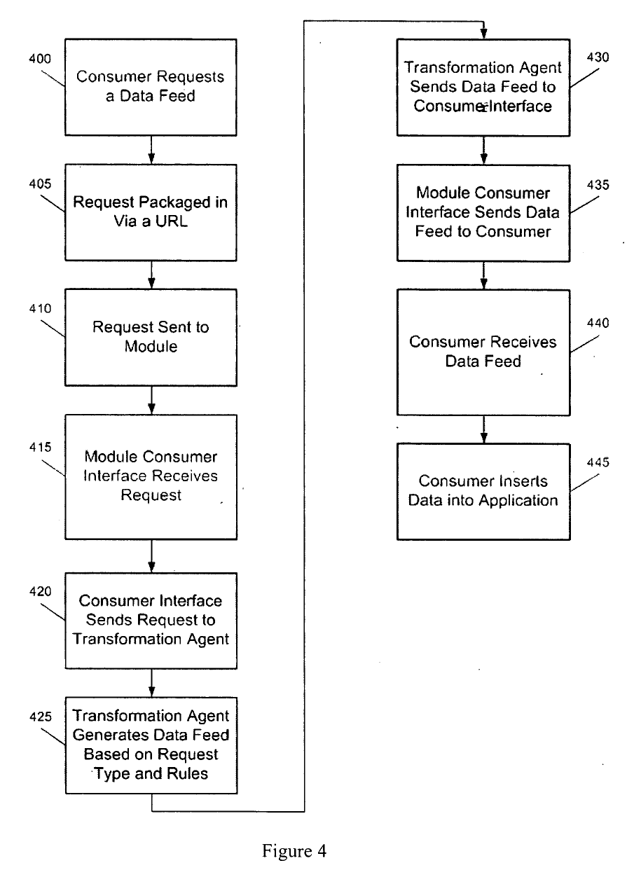

FIG. 4 illustrates a preferred method for a remote consumer to interact with a publicasting module.

Beginning at step 400, a device data consumer requests a data feed from a publicasting module. The data consumer could be a spreadsheet, a database, an RSS news reader, or other entity that requires the device data. The consumer may expect a response immediately similar to accessing a web page or it may expect a response after some time has passed. If the consumer expects a delayed response, the request could be characterized as a subscription. Under a subscription, when the module has prepared the data feed, it will send the feed to all those that have subscribed and are expecting a response.

At step 405, the request for the data feed is packaged by the consumer as a URL, for instance, requesting a data feed that adheres to an RSS XML format. Other request formats beyond URLs are also contemplated including direct network connections, SQL queries, peer-to-peer communications, or other client-server requests. Generally, the request is packaged according to the natural communication mechanism required by the consumer. Natural mechanisms include RSS for a news reader, web services for web services applications, SQL for database applications, or other contemplated mechanisms that exist or will be developed. Even though the request is formatted according to the natural manner for the consumer, it still must be framed for the actual transport media.

At step 410, the request is placed on the transport media. Media includes packet switched networks based on Ethernet or other physical media including wireless. Typically, layered protocols stacks such as TCP/IP are used to transport the data.

At step 415, the publicasting module's consumer interface receives the request from the consumer. The consumer interface understands both the physical media used for transporting the request as well as the upper layer protocols. In addition, the consumer interface is capable of determining which set of publishable data to request from the transformation agent based on the natural mechanism used by the consumer to make the request. For instance, if the request is a URL representing an RSS feed, the consumer interface will request publishable data from the transformation agent in the form of an RSS feed. Additionally, if the request comes in the form of an instant message, similarly the output agent will request the publishable data in an instant messaging format. Therefore, the consumer interface comprises sufficient intelligence to understand multiple application level protocols as determined by the developer of the module.

At step 420, the consumer interface passes the request to the transformation agent. Generally, the method used to pass the request is based on techniques described earlier. Once the transformation agent receives the request, the actual data feed can be generated.

At step 425 the transformation agent generates the data feed that is intended for the consumer. When the transformation agent generates the data feed, the feed may already exist in memory or on the data store so the agent does not need to do much work. For instance, the in case of an RSS feed, the transformation agent may have been collecting device data and have it pre-packaged and ready to go when requested or when it is time to fulfill a subscription. Alternatively, the agent may have to build the data feed in real-time based on information in the data store, device data, or state information. For instance, if the consumer requests a comma separated value (CSV) data set for a spreadsheet, the transformation agent must read all necessary elements, convert them to text or numbers, and insert commas before the feed is ready to be published.

At step 430, the transformation agent passes the resulting data feed back to the consumer interface for publishing. This step is the reciprocal of step 620.

At step 435, the consumer interface returns the data feed to the consumer. Again, the response to the consumer's request may be delayed depending on the mode and type of the original request. In addition, depending on the number of remote consumers that have subscribed to a data feed, the consumer interface may publish the data feed via a number of mechanisms including unicasting to a single consumer, multicasting to a group of consumers, broadcasting to all hosts on a network, or anycasting to at least one receptive consumer.

At step 440 the consumer receives the request and unpacks the data feed from the framing used by the transport media. At this point, the consumer now has data in its final format.

At step 445, the consumer takes the data and inserts the data into its final destination without modification. The destination could include cells in a spreadsheet, display items in an RSS news reader, populating data structures, fields in a database, or API based on web services.

Thus, specific embodiments and applications of publicasting modules have been disclosed. It should be apparent; however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. A publicasting module that publishes data from a device to a remote consumer comprising:
a device interface that receives device data from the device;
a transformation agent that transforms the device data to publishable data in a format requested by the consumer; and
a consumer interface that publishes the publishable data to the consumer.

2. The module of claim 1, wherein the transformation agent transforms the device data to additional formats requested by other consumers, and the consumer interface publishes the publishable data in the additional formats to the other consumers.

3. The module of claim 1, wherein the consumer interface publishes the publishable data via at least one of unicasting, multicasting, broadcasting, and anycasting.

4. The module of claim 1, wherein the module has physical dimensions that allow the module to reside in a standard physical connector.

5. The module of claim 4, wherein the standard physical connector comprises at least one of an RJ-45 jack and a serial connector.

6. The module of claim 4, wherein the module is a chip.

7. The module of claim 1, wherein the transformation agent provides state for the device.

8. The module of claim 1, wherein the device has limited networking capability.

9. The module of claim 1, wherein the device does not natively have publicasting capability.

10. The module of claim 1, wherein the device interface comprises a serial interface.

11. The module of claim 10, wherein the serial interface has no more than two pins, including ground.

12. The module of claim 10, wherein the serial interface comprises a programmable I/O pin.

13. The module of claim 10, wherein the serial interface comprises at least one of an RS 232, RS 485, and a RS 422 interface.

14. The module of claim 10, wherein the serial interface comprises at least one of a Firewire, USB, and an Ethernet interface.

15. The module of claim 10, wherein the serial interface comprises at least one of a I2C, SPI, CAN, and a Profibus interface.

16. The module of claim 1, wherein the device interface further comprises an API.

17. The module of claim 1, wherein the device interface further comprises a parallel interface.

18. The module of claim 1, wherein the consumer interface comprises a packet switched network.

19. The module of claim 18, wherein the packet switched network comprises one of Ethernet, ATM, frame relay, and the Internet.

20. The module of claim 18, wherein the packet switched network comprises at least one of an intranet and Internet.

21. The module of claim 18, wherein the consumer interface comprises an API.

22. The module of claim 1, wherein the transformation agent employs updateable transformation rules

23. The module of claim 1, wherein the module comprises a plurality of transformation agents.

24. The module of claim 1, wherein the consumer comprises a publicasting module.

25. The module of claim 1, wherein the module publishes the publishable data to no more than two remote consumers.

26. The module of claim 1, wherein the module publishes the publishable data to a plurality of remote consumers.

27. The module of claim 1, wherein the module comprises no more than two device interfaces.

28. The module of claim 1, wherein the module comprises a plurality of device interfaces.

29. The module of claim 1, wherein the publishable data format comprises an XML based format.

30. The module of claim 29, wherein the XML based format is at least one of RSS, ATOM, SOAP, and WSDL.

31. The module of claim 1, wherein the publishable data format comprises an instant messaging protocol.

32. The module of claim 1, wherein the publishable data format comprises SQL commands and requests.

33. The module of claim 1, wherein both consumer and device interface comprise standard network interfaces and the module may be located at any distance from either consumer or device.

34. The module of claim 1 wherein the device interface and consumer interface utilize the same physical layer hardware, firmware or software.

35. A method of making device data available to a remote consumer:
providing a publicasting module that communicates with a device at least in part through a device interface;
receiving device data from the device through the device interface;
transforming device data into publishable data in a format requested by the remote consumer; and
communicating the publishable data to the remote consumer through a consumer interface.

36. The method in claim 35, wherein the module responds to requests made by the remote consumer comprising URLs.

37. The method of claim 36, wherein the module's response to the requests made by the remote consumer comprises publishing a data feed.

38. The method of claim 37, wherein the step of publishing the data feed comprises utilizing an RSS feed, an ATOM feed, instant messages, and web services.

39. The method of claim 35, wherein the transformation agent transforms device data to publishable data via updateable transformation rules.

40. The method of claim 35, wherein the remote consumer inserts the publishable data from the device into an application.

41. The method of claim 40, wherein the application places the publishable data from the device into a data store.

42. The method of claim 35, wherein the remote consumer makes requests via an API.

43. The method of claim 35, wherein the module communicates with the device via an API.

44. The method of claim 35, wherein the modules responds to requests from a plurality of consumers.

45. The method of claim 35, wherein the transformation agent alters the publishable data format based on the format of the remote consumer's request.

46. The method of claim 35, further comprising the module communicating with the remote consumer bi-directionally.

47. The method of claim 35, further comprising the module communicating with the device bi-directionally.

48. The method of claim 35, further comprising the module communicating the publishable data as a data feed.

49. The method of claim 48, further comprising generating revenue via at least one of selling, renting, and licensing the data feed.

50. A system for inserting device data into an application comprising:
a device with limited networking capability;
an application utilizing the device data;
a publicasting module that communicates with the device via a device interface and sends device data in a desired format to the application through a consumer interface; and
the module further comprising a transformation agent that transforms device data into the desired format for the application.

51. A publicasting module that publishes data from a device to a remote database comprising:
an RS-232 interface that receives device data from the device;
a transformation agent that transforms the device data to publishable data utilizing SQL as a publishable data format; and
an Ethernet consumer interface sending publishable data to the database.

52. A publicasting module that publishes data from a device to a remote application comprising:
an RS-232 interface that receives device data from the device;
a transformation agent that transforms the device data to publishable data utilizing web services as an publishable data format; and
an Ethernet consumer interface sending publishable data to the remote application.
